(19) United States
(12) Patent Application Publication
(10) Pub. No.: US 2014/0117406 A1
(43) Pub. Date: May 1, 2014

(54) REVERSE BLOCKING MOS SEMICONDUCTOR DEVICE AND MANUFACTURING METHOD THEREOF

(71) Applicant: FUJI ELECTRIC CO., LTD., KAWASAKI-SHI (JP)

(72) Inventor: Mitsuhiro KAKEFU, Matsumoto-city (JP)

(73) Assignee: FUJI ELECTRIC CO., LTD., KAWASAKI-SHI (JP)

(21) Appl. No.: 14/055,551

(22) Filed: Oct. 16, 2013

(30) Foreign Application Priority Data
Oct. 30, 2012 (JP) 2012-239042

(51) Int. Cl. H01L 29/739; H01L 21/265; H01L 29/66

(52) U.S. Cl. CPC H01L 29/7393; H01L 29/66325; H01L 21/265
USPC 257/139; 438/135

(57) ABSTRACT

A reverse blocking IGBT is disclosed in which a lifetime control region formed by helium ion irradiation is selectively provided in a region within a range approximately corresponding to the planar pattern of a p-type base region in the direction along the principal surface of a silicon semiconductor substrate of n-type and within a range from the upward vicinity to the downward vicinity of the p-n junction on the bottom of the p-type base region in the direction of the depth of the silicon semiconductor substrate. This can provide a reverse blocking MOS semiconductor device capable of further decreasing a reverse leakage current less than the current in a previous device while making the influence on an on-state current small.

### BACKGROUND OF THE INVENTION

A. Field of the Invention

The present invention relates to a reverse blocking MOS semiconductor device such as a reverse blocking IGBT used for a system such as an electric conversion system and a manufacturing method of the device. Here, the term “IGBT” means an insulated gate bipolar transistor.

B. Description of the Related Art

In recent years, in electric power conversion circuits carrying out conversions such as AC (Alternating Current)/AC conversion, AC/DC (Direct Current) conversion, and DC/AC conversion, the use of a matrix converter is known as a directly linked conversion circuit capable of necessitating no DC smoothing circuit formed of components such as electrolytic capacitors and DC reactors. The matrix converter is used under an AC voltage to therefore necessitate bidirectional switching devices, capable of controlling currents in both forward and reverse directions, for a plurality of switching devices mounted on the matrix converter.

Recently, from the viewpoints of making a circuit small, light-weight, highly efficient, fast and inexpensive, a device has been receiving attention in which a bidirectional switching device is formed of two reverse blocking IGBTs in inverse parallel connection as is shown in an equivalent circuit diagram in FIG. 6. This is because reverse blocking IGBTs in inverse parallel connection are advantageous because they necessitate no diode for blocking a reverse voltage. That is, the reverse blocking IGBT is named as a device having the characteristics of making a reverse breakdown voltage to the same extent as a forward breakdown voltage and, along with this, enhancing voltage-withstand reliability.

While, in an ordinary IGBT used for a related electric power conversion circuit, like an ordinary transistor or an ordinary MOSFET having no reverse voltage-withstand characteristic, no effective reverse voltage-withstand characteristic was required. Thus, an IGBT, having performance with a reverse breakdown voltage being lower compared with a forward breakdown voltage and with voltage-withstand reliability also being low, was sufficient when used in such a conversion circuit.

FIG. 2 is a cross sectional view schematically showing a related reverse blocking IGBT. The reverse blocking IGBT has a planar MOS gate structure included in active region 110 with a main current flowing therein in the middle section on the top surface side of silicon semiconductor substrate 1 of a device chip. On the outside of active region 110, voltage-withstand structure region 120 is provided. Furthermore, in the position surrounding the outer periphery of voltage-withstand structure region 120, p-type isolation region 31 is provided which connects between both of the top and bottom principal surfaces of silicon semiconductor substrate 1 with a diffused region with a conduction type different from the conduction type of semiconductor substrate 1. In order to form p-type isolation region 31 with such a considerable depth only by thermal diffusion carried out from one side of the principal surfaces, the diffusion depth must be provided with a depth larger than the thickness of the substrate determined by a breakdown voltage. This requires a high temperature and long term thermal diffusion drive-in processing. See JP-A-2006-80269, FIG. 7 and Example 1. For example, when a reverse blocking IGBT of the withstand voltage class of 600V is formed with the wafer thicknesses of approximately 50 μm and a reverse blocking IGBT of the withstand voltage class of 1200V is formed with the wafer thicknesses of approximately 180 μm, the high temperature and long thermal diffusion drive-in processing is to be carried out at 1300° C. for approximately 100 hours for the reverse blocking IGBT of the withstand voltage class of 600V (when the diffusion depth is on the order of 100 μm) and is to be carried out at 1300° C. for approximately 300 hours for the reverse blocking IGBT of the withstand voltage class of 1200V (when the diffusion depth is on the order of 200 μm).

The semiconductor regions of the foregoing related reverse blocking IGBT will be briefly explained. Active region 110 is a region to be a path of the main current of the vertical IGBT provided with constituents such as n⁻-type drift region 1′, p-type base region 2, n⁺-type emitter region 3, gate oxide film 4, gate electrode 5, interlayer dielectric 6, emitter electrode 9, p-type collector region 10 and collector electrode 11. P-type isolation region 31 is a diffused region of p-type formed by thermal diffusion of boron atoms with a depth more than the depth reaching from the top surface of silicon semiconductor substrate 1 to p-type collector region 10 on the bottom surface side. By p-type isolation region 31, the end of the p-n junction face between p-type collector region 10 and n⁻-type drift region 1′ as a reverse voltage-withstand junction is not exposed to chip side end surface 12 of the reverse blocking IGBT to be a cross sectional surface when the wafer of the reverse blocking IGBTs is cut into chips, but appears on top surface 13 of voltage-withstand structure region 120 as the end of the p-n junction face between the n⁻-type drift region 1 and p-type isolation region 31 while being protected by an insulating film, which can enhance reverse voltage-withstand reliability.

FIG. 7 shows a series of cross sectional views illustrating the manufacturing steps in order in (a) to (d) in a related impurity diffusion process of forming p-type isolation region 31 required for the foregoing reverse blocking IGBT. First, on the top surface side of thick silicon semiconductor substrate 100 with a thickness of 500 μm or more, thermal oxide film 101 with a thickness on the order of 0.8 μm to 2.5 μm is formed as a dopant mask ((a) of FIG. 7). By carrying out the patterning of thermal oxide film 101, opening 102 for doping impurities is formed ((b) of FIG. 7). Then, implantation 103 of boron ions as impurity ions is carried out through opening 102 ((c) of FIG. 7). Subsequent to this, thermal oxide film 101 used for the dopant mask is removed. Thereafter, thermal diffusion drive-in processing is carried out at a high temperature (1300° C.) for a long period (100 hours to 300 hours) to form p-type diffused region 104 with a depth of the order of 100 μm to 200 μm ((d) of FIG. 7). P-type diffused region 104 is used as the foregoing p-type isolation region 31. After this, an oxide film is formed again on the top surface of silicon semiconductor substrate 100 for carrying out the process of forming the foregoing MOS gate structure and necessitated top surface side functional regions. For increasing a switching speed, reducing a reverse leakage current and enhancing reverse recovery capability, a carrier lifetime control process (not shown) with electron beam irradiation is carried out on the whole surface of silicon semiconductor substrate 100. Following this, the bottom side of silicon semiconductor substrate 100 is ground to the bottom of p-type diffused region 104 for removing the section surrounded by a broken line, by which thin silicon semiconductor substrate 1 is provided. On the bottom surface of silicon semiconductor substrate 1, p-type collector region 10 (not shown in (d) of FIG. 7) and collector electrode 11 (not shown in (d) of FIG. 7) are formed. Then, silicon semiconductor substrate 1 is cut along scribe line 105 shown by dot and dash line 105 ((d) of FIG. 7). Cut silicon semiconductor substrate 1 becomes the related reverse blocking IGBT shown in FIG. 2.

In a reverse blocking IGBT, however, high temperature and long term thermal diffusion drive-in processing is required for forming deep p-type isolation region 31 as was explained in the foregoing. Thus, accompanied with this, a number of interstitial oxygen atoms are introduced into silicon semiconductor substrate 1 to induce a phenomenon of making oxygen atoms donors, by which oxygen precipitations or crystal defects are formed. As a result, not only does a reverse leakage current produced in the vicinity of the p-n junction in silicon semiconductor substrate 1 become higher compared with a reverse leakage current in an ordinary IGBT, but also the possibilities of largely degrading the breakdown voltage and the reliability of thermal oxide film 101 formed on silicon semiconductor substrate 1 become high. For example, FIG. 8 is a characteristic diagram showing reverse current I to reverse voltage V characteristics as voltage-withstand characteristics of the related reverse blocking IGBT shown in FIG. 2 having p-type isolation region 31 formed by the foregoing related impurity diffusion process shown in FIG. 7. Letting silicon semiconductor substrate 1 have few crystal defects presented therein, reverse current I to reverse voltage V characteristic shows a hard form with a sharp corner at the rising of reverse current I as curve (a). In actuality, however, silicon semiconductor substrate 1 includes regions with many crystal defects due to the foregoing oxygen precipitations to provide reverse current I to reverse voltage V characteristic with a soft form having a gradual rising of reverse current I and showing that a reverse leakage current is large as curve (b). The comparison of the reverse current with the characteristic (a) and the reverse current with the characteristic (b) at a specified breakdown voltage (600V or 1200V, for example) shown by a dot and dash line in FIG. 8 shows that the reverse current with the soft form characteristic (b) is larger compared with the reverse current with the hard form characteristic (a), that is, that there is a large amount of reverse leakage current with the soft form characteristic (b). A large amount of a reverse leakage current is liable to cause heat deterioration to also degrade voltage-withstand reliability.

For reducing a reverse leakage current, increasing a switching speed and enhancing reverse recovery capability in this way, lifetime control of carriers was carried out even in the past by the electron beam irradiation on the whole surface of the silicon semiconductor substrate as was explained in the foregoing. However, an increase in the amount (dose) of the electron beam irradiation causes degradation in an on state voltage that is in a trade-off relation to the foregoing reduction in a reverse leakage current, increase in a switching speed and enhancement in reverse recovery capability, which imposed limitations to the lifetime control of carriers by the electron beam irradiation.

Carrier lifetime control methods other than the electron beam irradiation disclosed in publicly known documents will be explained. JP-A-2007-59550 has, in Paragraph [0005], a description of local lifetime control of carriers carried out by helium ion irradiation.

In this way, for local lifetime control of local minor carriers of a semiconductor device, an implantation (irradiation) method with charged particles such as protons (hydrogen ions) or helium ions has been publicly known. The implantation of such charged particles causes their inelastic collisions with electrons in a crystal and their elastic collisions with nuclei. In particular, in elastic collisions with nuclei, silicon atoms are ejected from their respective lattice sites to form a large number of crystal defects. At the same time, the lifetime of a carrier at the site at which the crystal defect is formed can be locally shortened.

Namely, the implantation method of the charged particles is characterized by the capability of controlling the depth (position) of crystal defects by choosing energy of implanted ions and the capability of controlling the amount of crystal defects, i.e., the degree of shortening the lifetime of carriers by changing the amount of implanted ions. Such kinds of charged particles include not only protons and helium (He) ions, but also electrons. However, electron beam irradiation is different from irradiation with other charged particles in that defects are formed in the whole silicon semiconductor substrate when the substrate is irradiated with an electron beam. When the silicon semiconductor substrate is irradiated with protons or helium ions other than an electron beam, crystal defects can be formed only in a specified region in the substrate.

Furthermore, JP-A-2005-340528 describes that short lifetime region 32 of carriers is formed by irradiation with helium ions so that the peak position of the helium ions is within a range from 80% to 120% of the depth of a diffused region formed in the surface layer of an n—semiconductor layer, though the object of the irradiation is different from the object of the invention in such a way that the irradiation is carried out for obtaining a sufficiently high di/dt blocking capability, the blocking capability against the attenuation rate of a current i with respect to a time t, to such an extent that the device can withstand a lightning surge. See claim 6.

As was explained in the foregoing, a reverse blocking IGBT is known to be liable to have a reverse leakage current in a semiconductor substrate increased when a reverse voltage is applied. Moreover, in the case of a reverse blocking IGBT, it becomes a problem that a reverse leakage current is particularly liable to cause a thermal runaway. The reason for this will be explained. As is shown in FIG. 2, when a reverse voltage is applied to a semiconductor device having a p-n junction, electron-hole pairs are produced in a depletion layer extending from the reverse voltage-withstand junction (the p-n junction between n—type drift region 1′ and p-type collector region 10). Of the produced electron-hole pairs, electrons 50 flow to emitter electrode 9 and holes 51 flow into collector electrode 11 to thereby produce the reverse leakage current of the reverse blocking IGBT. While, the reverse blocking IGBT has a layer structure of a parasitic bipolar transistor (a p-n-p transistor with p-type base region 2 in FIG. 2 as an emitter, n⁻-type drift region 1′ as a base and p-type collector region 10 as a collector) in the inner layer structure thereof. In this way, a reverse blocking IGBT has a reverse voltage-withstand junction through which a large reverse leakage current flows and further contains a parasitic transistor. This causes an electron current of a reverse leakage current (the electron-hole pairs) to become the base current of the parasitic transistor, according to which holes 51 are injected from p-type base region 2 toward n⁻-type drift region 1′ to reach the reverse voltage-withstand junction (p-n junction), by which the reverse leakage current is amplified. In this way, in a reverse blocking IGBT, an originally large reverse leakage current comes to abruptly increase by a parasitic transistor when a reverse voltage is applied to make the reverse blocking IGBT liable to come to go into thermal runaway.

The invention was made with the foregoing problems taken into consideration to provide a reverse blocking MOS semiconductor device and a manufacturing method thereof, which device is capable of further decreasing a reverse leakage current less than the reverse leakage current in a previous device while making the influence on an on-state voltage small.

### SUMMARY OF THE INVENTION

The invention provides a reverse blocking MOS semiconductor device including: a first conduction type semiconductor substrate; a second conduction type base region selectively formed in the surface layer of one of the principal surfaces of the first conduction type semiconductor substrate; a first conduction type emitter region selectively formed on the surface in the second conduction type base region; a MOS gate structure including a gate electrode arranged over the surface of the second conduction type base region in an area between the first conduction type emitter region and the surface layer of a region of the first conduction type semiconductor substrate with an insulating film put in between; a voltage-withstand structure region of the first conduction type semiconductor substrate provided on the outside of the second conduction type base region; and a second conduction type isolation region formed so as to surround the voltage-withstand structure region and, along with this, extend from the one of the principal surfaces to the other, in which device an effective lifetime control region formed by irradiation with charged particles is selectively provided in a region within a range approximately corresponding to the planar pattern of the second conduction type base region in the direction along the principal surface of the first conduction type semiconductor substrate and within a range from the upward vicinity to the downward vicinity of the p-n junction on the bottom of the second conduction type base region in the direction of the depth of the first conduction type semiconductor substrate.

It is preferable that the charged particles are helium ions. It is further preferable that the range in the depth direction of the selectively provided effective lifetime control region formed by helium ion irradiation is from 80% to 120% of the depth of the second conduction type base region with the depth of the bottom surface of the second conduction type base region taken as the peak position of the distribution of the ranges of the applied helium ions. Moreover, it is preferable that the selectively provided effective lifetime control region formed by helium ion irradiation includes therein the corner section on each side of the bottom surface of the second conduction type base region. Furthermore, it is preferable that the second conduction type base region has a stripe-shaped planar pattern on one of the principal surfaces of the first conduction type semiconductor substrate and the planar pattern of the lifetime control region arranged so as to have the planar pattern of the second conduction type base region superposed thereon has a width approximately equal to the width of the planar pattern of the second conduction type base region. In addition, it is preferable that for providing the effective lifetime control region formed by helium ion irradiation, the helium ion irradiation is carried out with acceleration energy of any one selected from the range of 1 MeV to 30 MeV and with a dose of any one selected from the range of 1×10¹¹ cm⁻² to 3×10¹¹ cm⁻².

Moreover, for achieving the object and manufacturing the reverse blocking MOS semiconductor device, the invention provides a method of manufacturing a reverse blocking MOS semiconductor device, in which method, the helium ion irradiation is carried out with acceleration energy of any one selected from the range of 1 MeV to 30 MeV and with a dose of any one selected from the range of 1×10¹¹ cm⁻² to 3×10¹¹ cm⁻² so that the effective lifetime control region formed by helium ion irradiation is provided within the range of 80% to 120% of the depth of the second conduction type base region.

It is preferable that an ionized helium atom of 3He²⁺ is used as an ion species of the helium ion.

According to the invention, a reverse blocking MOS semiconductor device and a manufacturing method thereof can be provided which device is capable of further decreasing a reverse leakage current less than the current in a previous device while making the influence on an on-state current small.

### BRIEF DESCRIPTION OF THE DRAWINGS

The foregoing advantages and features of the invention will become apparent upon reference to the following detailed description and the accompanying drawings, of which:

FIG. 1 is a cross sectional view schematically showing a reverse blocking IGBT according to the invention;

FIG. 2 is a cross sectional view schematically showing a related reverse blocking IGBT;

FIG. 3 is an enlarged perspective cross sectional view showing a principal part in the vicinity of the top surface of the active region of the IGBT for illustrating a positional relation between a p-type base region and a lifetime control region formed by helium ion irradiation in the reverse blocking IGBT according to the invention;

FIG. 4 is a diagram showing a relationship between the dose of the helium ion irradiation according to the invention and the reverse leakage current;

FIG. 5 is a diagram showing a relationship between the dose of the helium ion irradiation according to the invention and the forward leakage current;

FIG. 6 is an equivalent circuit diagram showing a bidirectional switching device formed of two reverse blocking IGBTs in inverse parallel connection;

FIG. 7 shows a series of cross sectional views illustrating the manufacturing steps in order in (a) to (d) in a related impurity diffusion process of forming the p-type isolation region required for a related reverse blocking IGBT;

FIG. 8 is a characteristic diagram showing reverse current I to reverse voltage V characteristics as voltage-withstand characteristics of the related reverse blocking IGBT shown in FIG. 2 having the p-type isolation region formed by the related impurity diffusion process shown in FIG. 7;

FIG. 9 is a cross sectional view showing the principal part of the reverse blocking IGBT according to the example of the invention at the initial process step at which an opening for isolation diffusion is formed in an initial oxide film on a silicon semiconductor substrate in the process steps of manufacturing the reverse blocking IGBT;

FIG. 10 is a cross sectional view showing the principal part of the reverse blocking IGBT according to the example of the invention at the process step at which a p-type isolation region is formed around the silicon semiconductor substrate subsequent to the process step shown in FIG. 9;

FIG. 11 is a cross sectional view showing the principal part of the reverse blocking IGBT according to the example of the invention at the process step at which components of a reverse blocking IGBT and a lifetime control region formed by helium ion irradiation are provided subsequent to the process step shown in FIG. 10;

FIG. 12 is a cross sectional view showing the principal part of the reverse blocking IGBT according to the example of the invention at the process step at which the bottom surface of the silicon semiconductor substrate is ground to reduce the thickness thereof to expose the p-type isolation region on the ground surface subsequent to the process step shown in FIG. 11; and

FIG. 13 is a cross sectional view showing the principal part of the reverse blocking IGBT according to the example of the invention at the process step at which a p-type collector region and a collector electrode are formed on the ground surface of the bottom surface side of the silicon semiconductor substrate subsequent to the process step shown in FIG. 12.

### DETAILED DESCRIPTION OF SPECIFIC EMBODIMENTS

In the following, an example of the reverse blocking MOS semiconductor device according to the invention and a method of manufacturing thereof will be explained in detail with reference to attached drawings. In the specification and the attached drawings, a leading character “n” attached to the name of a layer or a region means that electrons are major carriers in the layer or the region and a leading character “p” attached to the name of a layer or a region means that holes are major carriers in the layer or the region. Moreover, a sign “+” attached to the leading character “n” or “p” means that the impurity concentration in the layer or the region is higher than that in the layer or the region without the sign and a sign “−” attached to the leading character “n” or “p” means that the impurity concentration in the layer or the region is lower than that in the layer or the region without the sign.

Furthermore, in the description of the example and in the attached drawings, similar arrangements will be denoted with the same reference numerals and signs, with redundant explanations thereof being omitted. In addition, in the attached drawings with reference to which the example will be explained are drawn neither to an accurate scale nor with an accurate dimensional proportion for the purpose of making the drawn items easy to see and easy to understand. Further, the invention is not limited to the descriptions of the examples explained in the following unless the descriptions depart from the spirit and scope of the invention.

### EXAMPLE

An example of a reverse blocking IGBT and a method of manufacturing thereof will be explained in detail with emphasis on the characterized parts thereof.

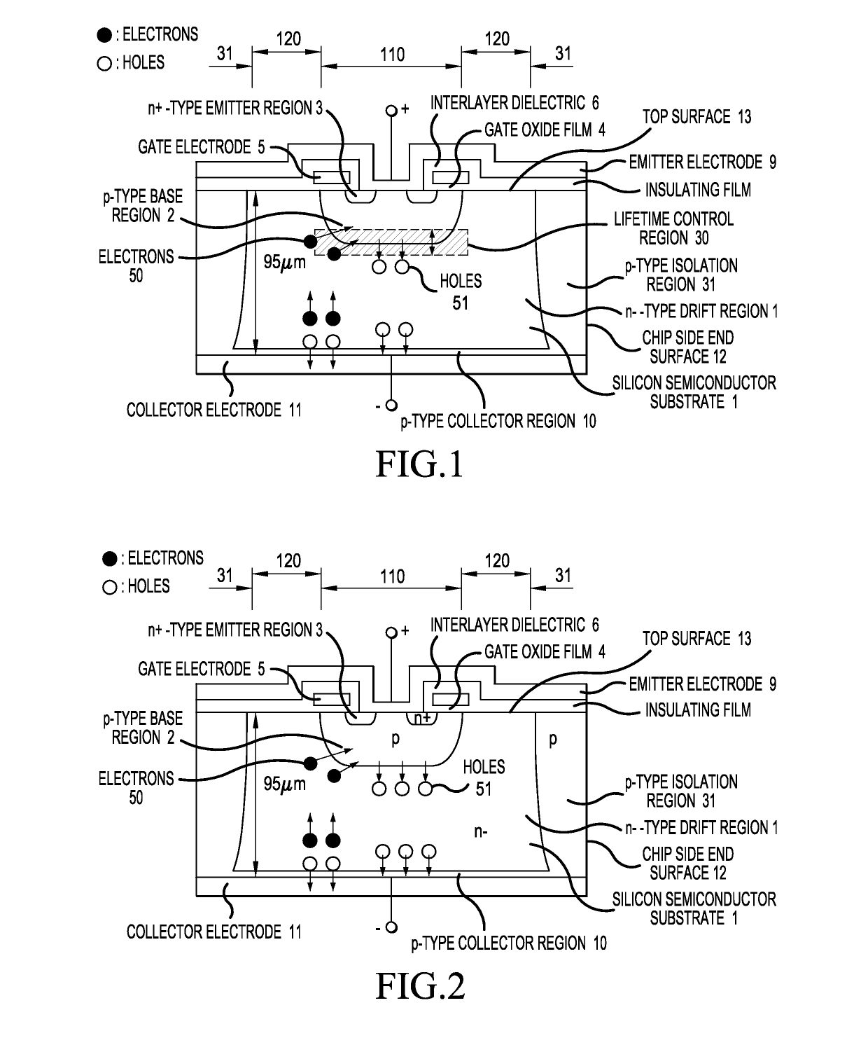

FIG. 1 is a cross sectional view schematically showing a reverse blocking IGBT with forward and reverse rated breakdown voltages of 600V according to the invention. The reverse blocking IGBT has active region 110 including constituents such as a planar MOS gate structure in the middle section on top surface 13 side of silicon semiconductor substrate 1 of a device chip.

In a device with a breakdown voltage of 600V, active region 110 is a region becoming the path of the main current of a vertical reverse blocking IGBT. In active region 110, on top surface 13 side of n⁻-type drift region 1′ with a thickness of 95 μm of silicon semiconductor substrate 1, a MOS gate structure is provided which is formed of p-type base region 2 with a depth of 3 μm, n⁺-type emitter region 3 with a depth of less than 1 μm, gate oxide film 4 and gate electrode 5. On top surface 13 side, interlayer dielectric 6 and emitter electrode 9 of an alloy film such as an aluminum alloy film are further provided. P-type collector region 10 and collector electrode 11 are provided on the bottom surface side.

Furthermore, active region 110 has lifetime control region 30 (hatched section) as the characteristic of the invention which region is formed of a helium ion irradiation region the range of which is controlled to be in a local one. By lifetime control region 30, lifetimes of electron-hole pairs produced in a depletion layer in the vicinity of p-type base region 2 and lifetimes of residual carriers presented in the vicinity of p-n junctions in large numbers are shortened. Thus, when a reverse voltage is applied, the reverse blocking IGBT has the number of electrons 50 decreased which flow into emitter electrode 9 to be eliminated, in response to which the number of holes 51 injected from p-type base region 2 to n⁻-type drift region 1′ is also decreased, i.e., the reverse blocking IGBT has the reverse leakage current thereof decreased.

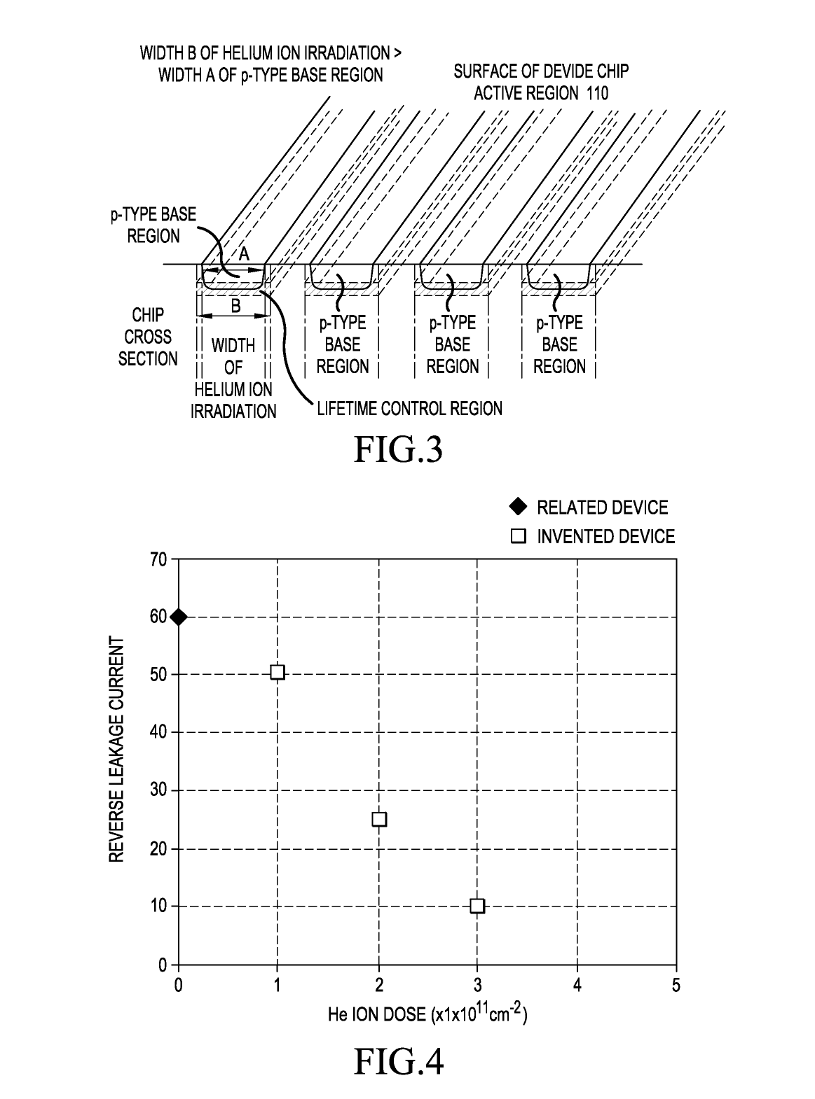

Helium ion irradiation is carried out with the use of a cyclotron as is already well known. FIG. 3 is an enlarged perspective cross sectional view showing a principal part in the vicinity of the top surface of active region 110 of the IGBT for illustrating a positional relation between p-type base region 2 and lifetime control region 30 formed by helium ion irradiation in the reverse blocking IGBT according to the invention. By the helium ion irradiation, as is shown in FIG. 3, lifetime control region 30 is formed at a hatched section positioned at a specified depth in a helium ion irradiation region provided along the surface direction of a surface stripe-shaped pattern of each of p-type base regions 2 with a width B equal to or a little larger than the width A of p-type base region 2. By such a helium ion irradiation region, the corner sections of the p-n junction at the bottom of p-type base region 2 are made included in lifetime control region 30, by which the concentration of the reverse leakage current can be lessened which is liable to occur at the corner sections. An opening pattern for the helium ion irradiation can be accurately formed with the use of a photoresist. Moreover, the helium ion irradiation region effectively functioning as lifetime control region 30 is formed only in a narrow region of above and below the bottom of p-type base region 2 in the thickness direction of the chip (substrate).

In addition, the reverse blocking IGBT according to the invention has p-type isolation region 31 arranged around the periphery of active region 110 so as to surround it with voltage-withstand structure region 120 put in between and connecting between both of the top and the bottom principal surfaces with a diffused region of the p-conduction type different from the n-conduction type of semiconductor substrate 1. The foregoing helium ion irradiation is preferably carried out with regions each of which is between p-type base regions 2 shown in FIG. 3, namely voltage-withstand structure region 120 and p-type isolation region 31 surrounding the periphery of n⁻-type drift region 1′ and active region 110, being shielded by a shield such as a mask so as to be subjected to the least possible amount of helium ion irradiation. This is because the helium irradiation of n⁻-type drift region 1′ and voltage-withstand structure region 120 may increase an on state voltage. Thus, although the width A of p-type base region 2 and the width B of the helium ion irradiation are in a relation of B>A in FIG. 3, the adverse effect of an increase in an on state voltage becomes larger as the width B becomes larger than the width A. Therefore, the width A and the width B are preferably nearer to B=A. Since the helium ion irradiation to p-type isolation region 31 damages the p-n junction between p-type isolation region 31 and n⁻-type drift region 1′ to increase a reverse leakage current, no irradiation to p-type isolation region 31 is preferable. The relation between such a local lifetime control region and the advantage of the invention will be explained later.

FIG. 9 to FIG. 13 are cross sectional views showing the manufacturing method of the reverse blocking IGBT according to the invention with respect to the principal part thereof in order of process steps. Here, the manufacturing method of a reverse blocking IGBT with the breakdown voltage of 1200V will be explained. As is shown in FIG. 9, on the top surface of silicon semiconductor substrate (FZ (Floating Zone) silicon substrate) 100 with a thickness of 500 μm or more and specific resistance of 800 Ωcm, oxide film (initial oxide film) 101 is formed with a thickness of the order of 0.8 μm to 2.5 μm is formed. In the subsequent process step, initial oxide film 101 is subjected to selective etching, by which opening 20 of a ring-shaped pattern with a width of 170 μm is formed in each of device chip regions in silicon semiconductor substrate 1. Opening 20 is that for carrying out isolation diffusion and is formed so as to surround the region to be active region 110 where the MOS structure is formed in the central section of each of the device chip areas and the periphery of the region to be voltage-withstand structure region 120 around active region 110.

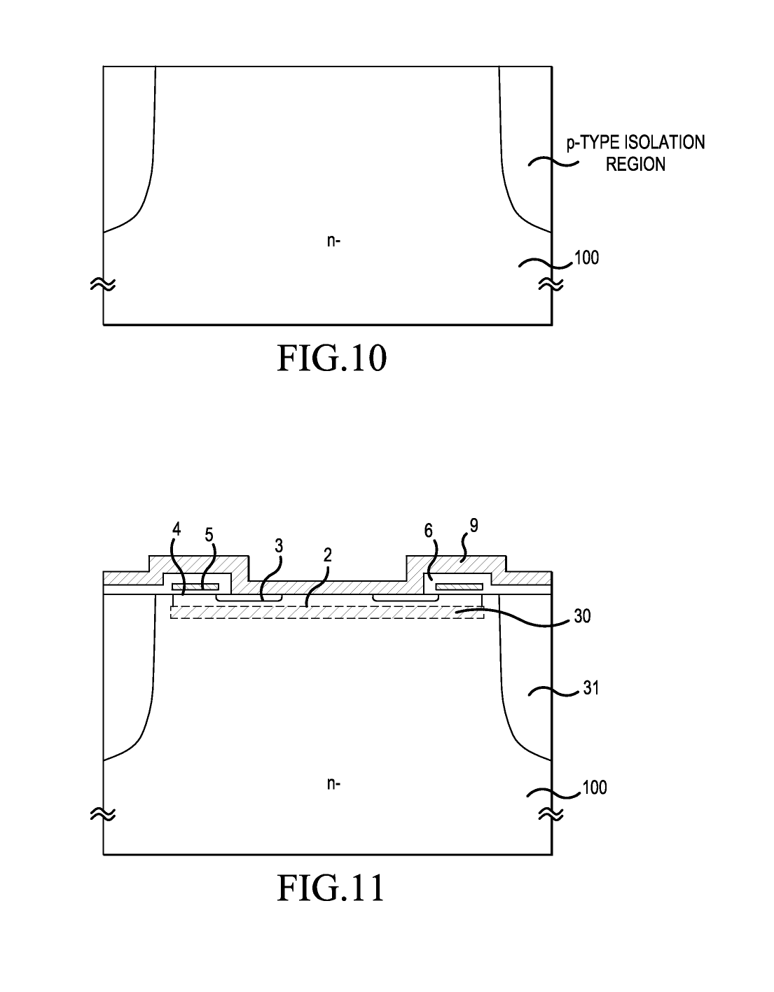

Thereafter, by using initial oxide film 101 as a dopant mask, boron ions as p-type impurities are implanted from opening 20. After the boron ion implantation, initial oxide film 101 used as the dopant mask is removed. Then, the heat treatment of silicon semiconductor substrate 100 is then carried out at a high temperature (1300° C.) for a long time (300 hours to 330 hours) to form p-type isolation region 31 with a depth of the order of 200 μm (FIG. 10). By p-type isolation region 31, the end of the p-n junction face between p-type collector region 10 and n⁻-type drift region 1′ as a reverse voltage-withstand junction is not exposed to chip side end surface 12 of the reverse blocking IGBT to be a cross sectional surface when the wafer of the reverse blocking IGBTs is cut into chips, but appears on top surface 13 of voltage-withstand structure region 120 as the end of the p-n junction face between n⁻-type drift region 1 and p-type isolation region 31 while being protected by an insulating film, which can enhance reverse voltage-withstand reliability.

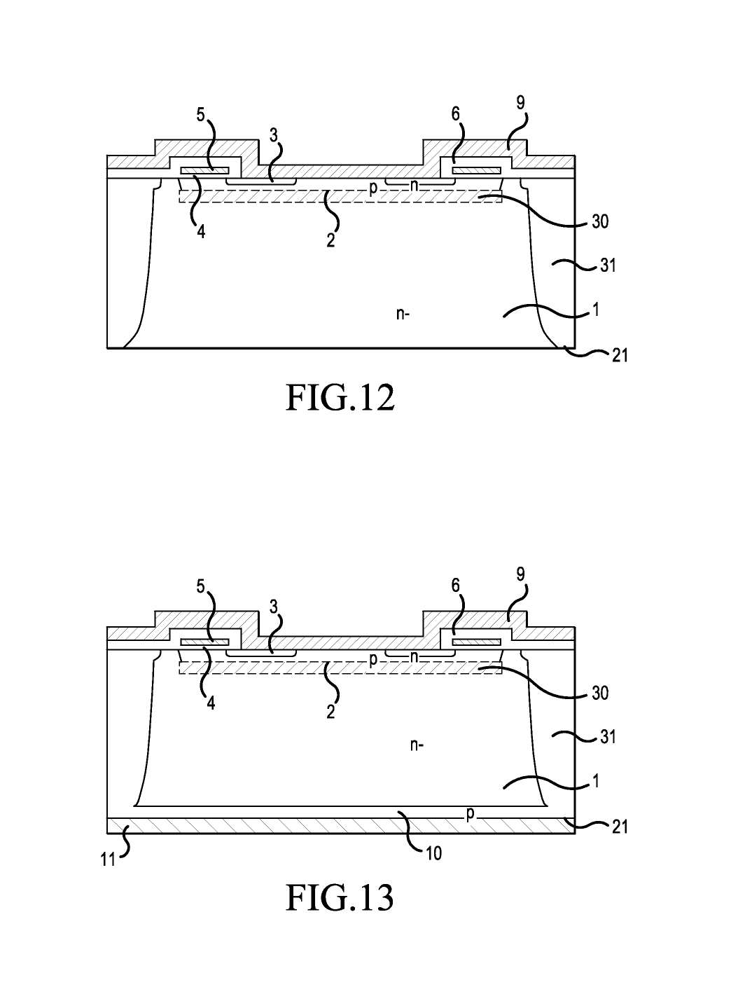

Next, as is shown in FIG. 11, an oxide film additionally formed on the top surface of silicon semiconductor substrate 100 during the formation of p-type isolation region 31 is removed. Thereafter, an oxide film is newly formed on the surface of the substrate and, with the oxide film or a polysilicon film deposited on the surface of the substrate used as a mask, constituents such as p-type base region 2 with a diffusion depth of 2 μm to 10 μm, for example 3 μm, n⁺-type emitter region 3, gate oxide film 4, gate electrode 5, interlayer dielectric 6 and emitter electrode 9 are formed with specified patterns by a publicly known method like a common method of manufacturing a planar gate IGBT. Furthermore, for a high speed operation, by carrying out helium (He) ion irradiation selectively along the surface pattern of p-type base region 2 and, also in the depth direction, locally in the region above and below the p-n junction face along the bottom surface of p-type base region 2, lifetime control region 30 characterized by the invention is formed. Then, as is shown in FIG. 12, the bottom surface of FZ semiconductor substrate 100 is ground to be provided as silicon semiconductor substrate 1 with the thickness thereof on the order of 180 μm to expose p-type isolation region 31 on ground surface 21.

Subsequent to this, as is shown in FIG. 13, boron ions are implanted with a dose of 1×10¹³ cm⁻² onto ground surface 21 on the bottom surface side of silicon semiconductor substrate 1 and low temperature annealing on the order of 350° C. is carried out for on the order of 1 hour to form p-type collector region 10 with the peak concentration of activated boron atoms of the order of 1×10¹⁷ cm⁻³ and the thickness of the order of 1 μm. P-type collector region 10 on the bottom surface and p-type isolation region 31 are made into electrically conductive connection. After collector electrode 11 that is the same as the related one is formed, silicon semiconductor substrate 1 is sliced into individual chips each of which is completed as the reverse blocking IGBT according to the invention.

The relations among the lifetime control region of the reverse blocking IGBT according to the invention, a method of forming the region and an advantage of the invention will be explained in the following. The process steps other than the process steps according to the method of forming the lifetime control region can be made to be the same as the process steps in the method of manufacturing a related reverse blocking IGBT.

The relations among lifetime control region 30 controlled to be within a local range as the characteristic of the reverse blocking IGBT with a breakdown voltage of 600V, a method of forming region 30 and an advantage of region 30 will be explained in the following.

For light ions to be charged particle ions for irradiation, ions such as protons and helium ions can be used. In particular, helium ions have no effect of becoming donors. Thus, the case of using helium ions will be explained in the following.

The irradiation with helium ions (³He²⁺) is carried out by using a cyclotron. The irradiation is carried out so that the ranges of the applied helium ions approximately having Gaussian distribution in the silicon semiconductor substrate 1 are within a range of 0.6 μm upward and within a range of 0.6 μm downward with the position of the surface at a depth of 3 μm of p-type base region 2, i.e., the bottom surface thereof made as the peak position, namely within a depth ranging from 2.4 μm to 3.6 μm, in which range effective lifetime control region 30 is formed.

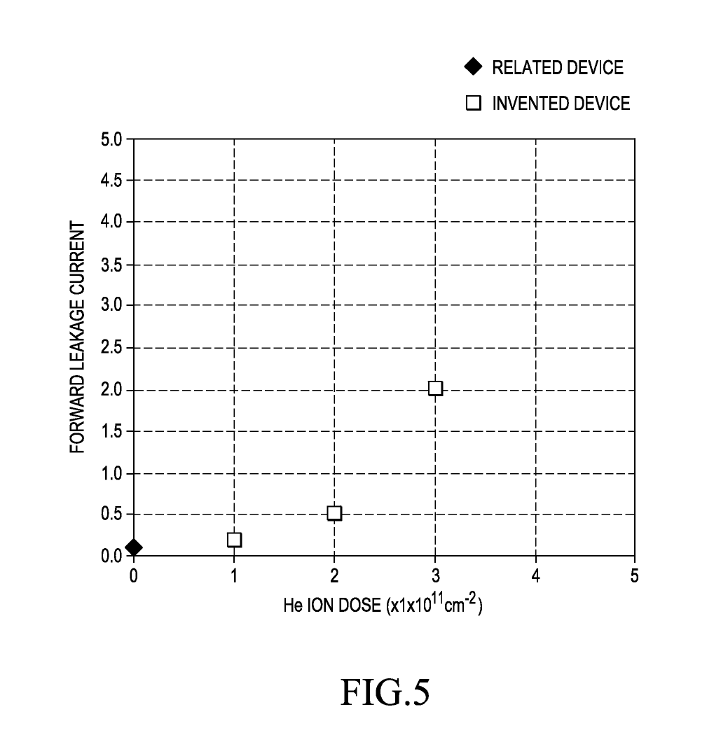

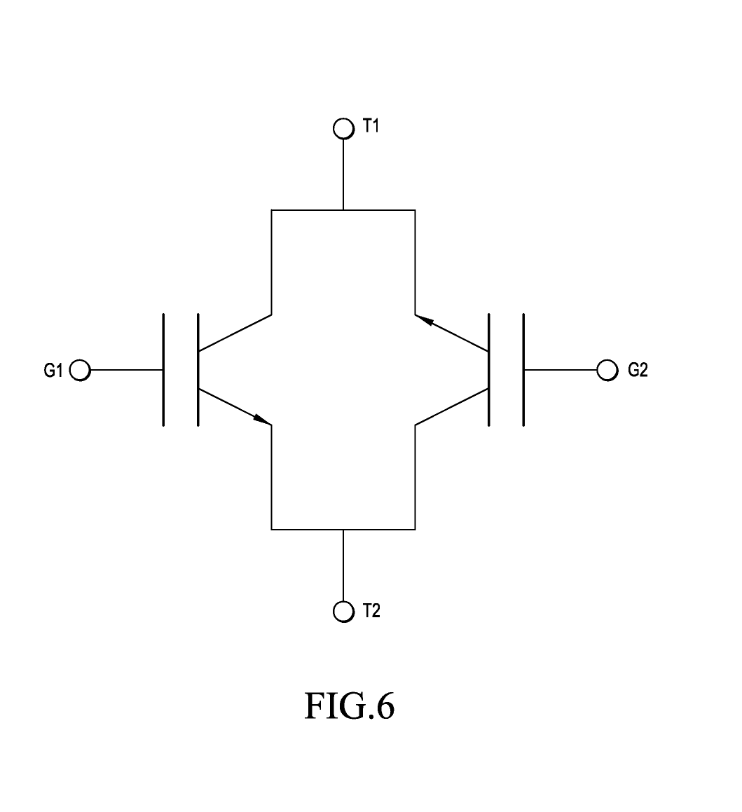

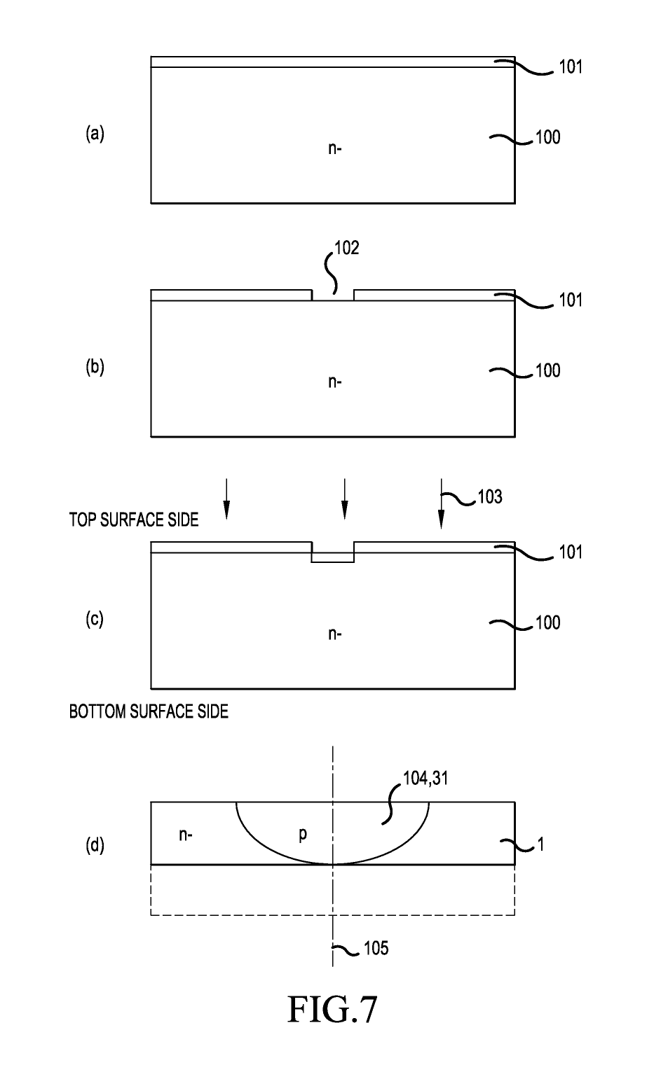

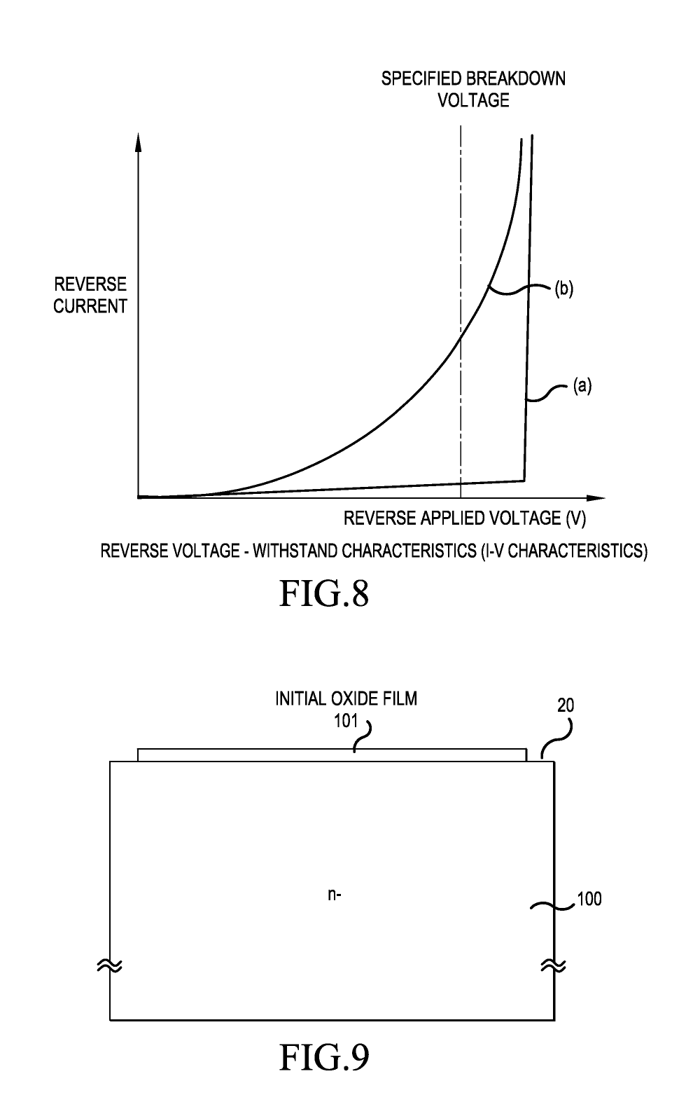

FIG. 4 is a diagram showing a relationship between the dose of the helium ion irradiation according to the invention and the reverse leakage current and FIG. 5 is a diagram showing a relationship between the dose of the helium ion irradiation according to the invention and the forward leakage current.

FIG. 4 shows the case in which helium ion irradiation is carried out onto a reverse blocking IGBT having a reverse voltage-withstand junction (the p-n junction between n⁻-type drift region 1′ and p-type collector region 10) with a large reverse leakage current and including a parasitic transistor with p-type base region 2 as an emitter, n⁻-type drift region 1′ as a base and p-type collector region 10 as a collector, and a reverse voltage is applied to the IGBT. In this case, it is shown that with the dose less than 1×10″ cm⁻², the contribution to the reduction in the reverse leakage current is small, but the reverse leakage current decreases with an increase in the dose when the dose becomes larger than 1×10¹¹ cm⁻². FIG. 5 shows that the forward leakage current due to the application of a forward voltage is originally small, but when the dose of the helium ion irradiation carried out onto the reverse blocking IGBT becomes 3×10″ cm⁻², the forward leakage current increases as 2.0 μA. Therefore, irradiation with a dose more than 3×10″ cm⁻² unfavorably has the possibility of further increasing the forward leakage current.

The reason that the forward leakage current increases with an increase in the dose is that crystal defects formed by the helium ion irradiation increase in the boundary between p-type base region 2 and n⁻-type drift region 1′ to increase crystal defects formed by the helium ion irradiation, by which damages to the p-n junction are increased. Therefore, the dose of the helium ion irradiation is preferably between 1×10″ cm⁻² and 3×10″ cm⁻².

A specific example of the condition of helium ion irradiation is given as that of the irradiation with ions ³He²⁺ with acceleration energy of 23 MeV, for example, carried out so that the peak of the number of helium ions comes on the p-n junction face on the bottom surface of p-type base region 2 with the diffusion depth of 3 μm. The acceleration energy can be chosen from a range of the order from 1.0 to 30 MeV depending on the depth of p-type base region 2. Furthermore, the dose of helium ions is determined to be within a range of 1×10¹¹ cm⁻² to less than 3×10¹¹ cm⁻². As a result, effective lifetime control region 30 is formed above and below the position of the depth of p-type base region 2 with each of the widths given on the order of 0.6 μm. In this way, a reverse leakage current can be effectively decreased while making the influence on an on state current small.

Moreover, lifetime control region 30 partly provided on the bottom of p-type base region 2 enables a reverse leakage current to be effectively made small. Along with this, lifetime control region 30 exerts no influence on the lifetime of residual carriers in regions other than the irradiation region to enable the influence on the increase in an on state voltage to be made small.

According to the foregoing example, the reverse blocking IGBT according to the invention effectively decreases holes injected again from p-type base region 2 into n⁻-type drift region 1′ to reduce holes reaching the reverse voltage-withstand junction region when biased in reverse. This provides the advantages of reducing a reverse leakage current and, along with this, being capable of minimizing adverse effect to an on state voltage.

Thus, a reverse blocking MOS semiconductor device such as a reverse blocking IGBT used for a system such as an electric conversion system and a manufacturing method of the device have been described according to the present invention. Many modifications and variations may be made to the techniques and structures described and illustrated herein without departing from the spirit and scope of the invention. Accordingly, it should be understood that the devices and methods described herein are illustrative only and are not limiting upon the scope of the invention.

What is claimed is:

1. A reverse blocking MOS semiconductor device comprising:
a first conduction type semiconductor substrate with two principal surfaces;
a second conduction type base region selectively formed in a surface layer of one of the principal surfaces of the first conduction type semiconductor substrate;
a first conduction type emitter region selectively formed in the second conduction type base region on its surface;
a MOS gate structure including a gate electrode arranged over the surface of the second conduction type base region in an area between the first conduction type emitter region and the surface layer of a region of the first conduction type semiconductor substrate with an insulating film put in between;
a voltage-withstand structure region of the first conduction type semiconductor substrate provided on the outside of the second conduction type base region; and
a second conduction type isolation region formed so as to surround the voltage-withstand structure region and extend from one of the principal surfaces to the other principal surface; and
an effective lifetime control region formed by irradiation with charged particles, selectively provided in a region within a range approximately corresponding to planar extent of the second conduction type base region in the direction along the principal surface of the first conduction type semiconductor substrate and within a range from the upward vicinity to the downward vicinity of the p-n junction on the bottom of the second conduction type base region in the direction of the depth of the first conduction type semiconductor substrate.

2. The reverse blocking MOS semiconductor device as claimed in claim 1, wherein the charged particles are helium ions.

3. The reverse blocking MOS semiconductor device as claimed in claim 2, wherein the range in the depth direction of the selectively provided effective lifetime control region formed by helium ion irradiation is from 80% to 120% of the depth of the second conduction type base region with the depth of the bottom surface of the second conduction type base region taken as the peak position of the distribution of the ranges of the applied helium ions.

4. The reverse blocking MOS semiconductor device as claimed in claim 2, wherein the selectively provided effective lifetime control region formed by helium ion irradiation includes therein the corner section on each side of the bottom surface of the second conduction type base region.

5. The reverse blocking MOS semiconductor device as claimed in claim 4, wherein the second conduction type base region has a stripe-shaped planar pattern on one of the principal surfaces of the first conduction type semiconductor substrate and the planar pattern of the lifetime control region arranged so as to have the planar pattern of the second conduction type base region superposed thereon has a width approximately equal to the width of the planar pattern of the second conduction type base region.

6. The reverse blocking MOS semiconductor device as claimed in claim 2, wherein for providing the effective lifetime control region formed by helium ion irradiation, the helium ion irradiation is carried out with acceleration energy of any one selected from the range of 1 MeV to 30 MeV and with a dose of any one selected from the range of 1×10¹¹ cm⁻² to 3×10¹¹ cm⁻².

7. A method of manufacturing a reverse blocking MOS semiconductor device wherein for manufacturing the reverse blocking MOS semiconductor device as claimed in claim 2, the helium ion irradiation is carried out with acceleration energy of any one selected from the range of 1 MeV to 30 MeV and with a dose of any one selected from the range of 1×10¹¹ cm⁻² to 3×10¹¹ cm⁻² so that the effective lifetime control region formed by helium ion irradiation is provided within the range of 80% to 120% of the depth of the second conduction type base region.

8. The method of manufacturing a reverse blocking MOS semiconductor device as claimed in claim 7, wherein an ionized helium atom of ³He²⁺ is used as an ion species of the helium ion.
